(19) United States
(12) Patent Application Publication
(10) Pub. No.: US 2012/0101761 A1
(43) Pub. Date: Apr. 26, 2012

(54) TEST METHOD AND APPARATUS FOR A DEVICE UNDER TEST

(75) Inventor: Haeng-jin LEE, Anyang-si (KR)

(73) Assignee: SAMSUNG ELECTRONICS CO., LTD., Suwon-si (KR)

(21) Appl. No.: 13/190,994

(22) Filed: Jul. 26, 2011

(30) Foreign Application Priority Data
Oct. 25, 2010 (KR) 10-2010-0104244

(51) Int. Cl. G01R 31/00

(52) U.S. Cl. 702/85

(57) ABSTRACT

A method and apparatus for testing a device under test (DUT) is provided. The test method including: a loading step of loading the at least one DUT; a soaking step of changing a temperature of the at least one DUT; during at least one of the loading step and the soaking step, a calibration step of updating a test program stored in a server or updating a calibration file; and a test step of carrying out an electrical test of the at least one DUT based on the test program or the calibration file. The test apparatus including a loader which loads the at least one DUT; a soak chamber for changing a temperature of the at least on DUT; a calibration unit for updating a test program stored in a server or updating calibration file, and a test unit for carrying out an electrical test of the at least one DUT based on the test program or the calibration file.

### CROSS-REFERENCE TO RELATED APPLICATIONS

This application claims the benefit of Korean Patent Application No. 10-2010-0104244, filed on Oct. 25, 2010, in the Korean Intellectual Property Office, the disclosure of which is incorporated herein in its entirety by reference.

### BACKGROUND

The inventive concept relates to test method and apparatus, and more particularly to, a test apparatus of a device under test (DUT) and a test method of the DUT using the test apparatus.

During a process of manufacturing a semiconductor device, a semiconductor package manufactured through a predetermined assembling process undergoes a test process of determining whether a specific function is fully implemented. A test apparatus performs the test process by applying an input signal to a device under test (DUT), receiving an output signal from the DUT, and comparing the output signal with expected data.

### SUMMARY

The inventive concept provides a test apparatus capable of improving a loss of time which occurs when a calibration step of improving the matching of signals transmitted between the test apparatus and a device under test (DUT) is performed, and a test method using the test apparatus.

According to an aspect of the inventive concept, there is provided a test method of at least one device under test (DUT), the test method including: a loading step of loading the at least one DUT; a soaking step of changing a temperature of the at least one DUT; during at least one of the loading step and the soaking step, a calibration step of updating a test program stored in a server or updating a calibration file; and a test step of carrying out an electrical test of the at least one DUT based on the test program or the calibration file.

The loading step and the calibration step may be performed simultaneously.

The test method may further includes a classification step of classifying the at least one DUT into defective and non-defective DUTs.

During the calibration step, the at least one DUT may not be connected to a test substrate. During the calibration step, the at least one DUT may not be electrically connected to an input cable and an output cable.

After the calibration step is completed, the test step may be performed. In addition, the test step may be performed during the calibration step, and the calibration step may be stopped during the test step. Moreover, the stopped calibration step may be performed again after the test step has been performed.

The calibration step may include updating the test program according to whether the type of the at least one DUT is changed, or whether a test process is changed.

In addition, the calibration step may include updating the calibration file according to whether the calibration file is stored. In this situation, the updating of the calibration file may include, if the calibration file is stored, loading the stored calibration file. Selectively, the updating of the calibration file may include, if the calibration file is not stored, preparing the calibration file.

The calibration step may include preparing the calibration file including timing skew data obtained by measuring a time taken to transmit electrical signals to the input cable or the output cable, reflect the electrical signals, and return the electrical signals.

During the test step, input signals may input into the at least one DUT and output signals may output from the at least one DUT are calibrated according to the calibration file.

According to another aspect of the inventive concept, there is provided a test method of at least one DUT. The method may include a loading step of loading the at least one DUT; a soaking step of changing a temperature of the at least one DUT; a first calibration step of updating a first calibration file during at least one of the loading step and the soaking step, and a first test step of carrying out an electrical test of the at least one DUT based on the first calibration file.

The test method may further include a second calibration step of updating a second calibration file after the first test step is performed, and carrying out the electrical test of the at least one DUT based on the second calibration file.

During the second calibration step, the at least one DUT may connected to a test substrate. In addition, during the second calibration step, the at least one DUT may be electrically connected to an input cable and an output cable.

According to another aspect of the inventive concept, there is provided a test apparatus of at least one DUT, which includes a controller, a handler for receiving a first operation signal from the controller, loading the at least one DUT; varying a temperature of the at least one DUT, a signal generator for generating an input signal applied to the at least one DUT based on a test program, a comparator for receiving an output signal of the at least one DUT and determining whether the at least one DUT is defective, a calibration unit for receiving a second operation from the controller, and correcting distortions of the input signal and the output signal, wherein the controller simultaneously transfers the first operation signal and the second operation signal to the handler and the calibration unit.

The test apparatus may further comprise an input cable for transmitting the input signal, and an output cable for transmitting the output signal, wherein, when the controller simultaneously transfers the first operation signal and the second operation signal to the handler and the calibration unit, the input cable and the output cable are not electrically connected to the at least one DUT.

### BRIEF DESCRIPTION OF THE DRAWINGS

Exemplary embodiments of the inventive concept will be more clearly understood from the following detailed description taken in conjunction with the accompanying drawings in which:

FIG. 1 is a schematic block diagram of a test apparatus, according to an exemplary embodiment;

FIGS. 2A and 2B schematically illustrate synchronization levels of input signals transmitted when the input signals are calibrated and are not calibrated, to explain a function of a calibration unit, according to an exemplary embodiment;

FIGS. 3A and 3B schematically illustrate synchronization levels of output signals transmitted when the output signals are calibrated and are not calibrated, to explain a function of a calibration unit, according to an exemplary embodiment;

FIGS. 4A through 4C are schematic flowcharts of a test method of a device under test (DUT), according to exemplary embodiments;

FIG. 5 is a schematic flowchart of a calibration step of the test method of FIG. 4A, according to an exemplary embodiment;

FIG. 6 is a schematic block diagram of a calibration unit included in the test apparatus of FIG. 1; and

FIGS. 7 and 8 are schematic flowcharts of a test method of a DUT, according to other exemplary embodiments.

### DETAILED DESCRIPTION OF THE EXEMPLARY EMBODIMENTS

The inventive concept will now be described more fully with reference to the accompanying drawings, in which exemplary embodiments of the inventive concept are shown. The inventive concept may, however, be embodied in many different forms and should not be construed as being limited to the embodiments set forth herein. Rather, these embodiments are provided so that this disclosure will be thorough and complete, and will fully convey the concept of the inventive concept.

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the term “comprising” when used in this specification, specifies the presence of stated features, integers, steps, operations, elements, and/or components, but does not preclude the presence or addition of one or more other features, integers, steps, operations, elements, components, and/or groups thereof. In the description, as used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing.

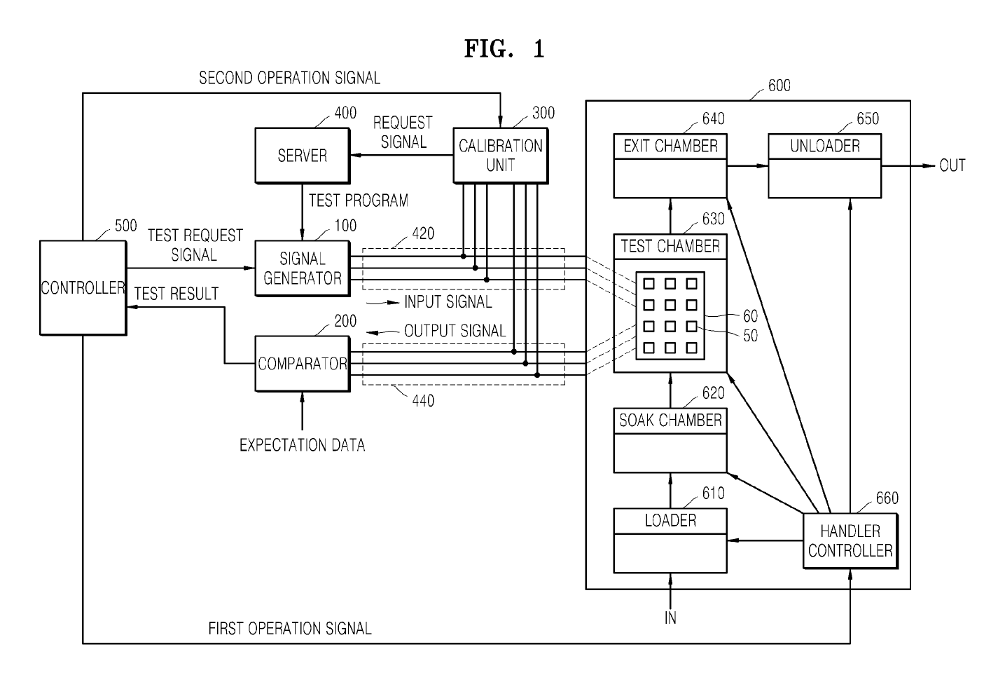

FIG. 1 is a schematic block diagram of a test apparatus, according to an exemplary embodiment of the inventive concept.

Referring to FIG. 1, the test apparatus may include a signal generator 100, a comparator 200, a calibration unit 300, a server 400, a controller 500, a handler 600, an input cable 420, and an output cable 440.

Signal generator 100 may receive a test program from server 400, and generate an input signal applied to a device under test (DUT) 50 based on the test program. If controller 500 transfers a test request signal to signal generator 100, signal generator 100 generates the input signal, and thus a test process of the DUT 50 begins. The input signal may be applied from the signal generator 100 to the DUT 50 through input cable 420.

Comparator 200 may receive an output signal of the DUT 50, and compare the output signal with expectation data to determine whether the DUT 50 is defective. The output signal is applied from DUT 50 to the comparator 200 through output cable 440. Further, comparator 200 transfers a test result regarding whether DUT 50 is defective, to controller 500.

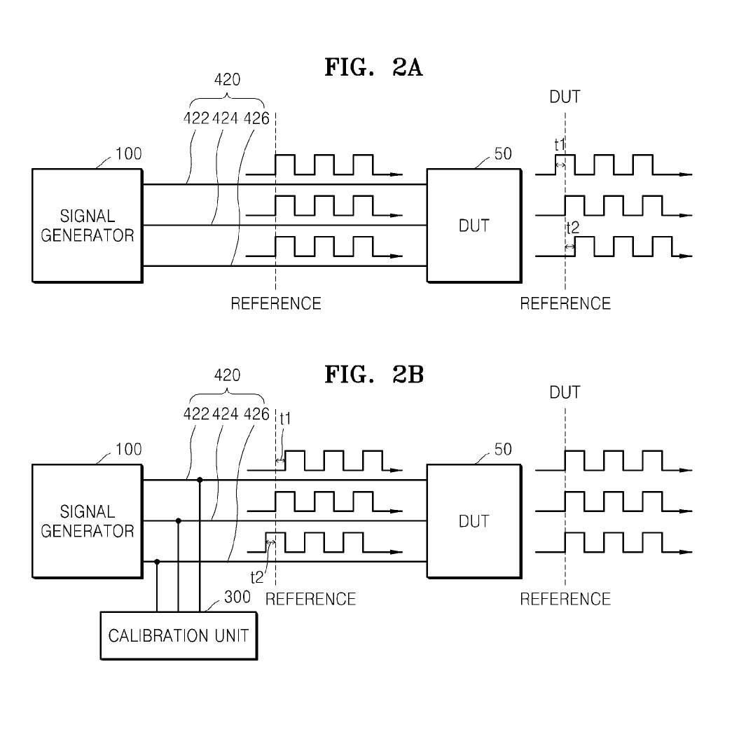

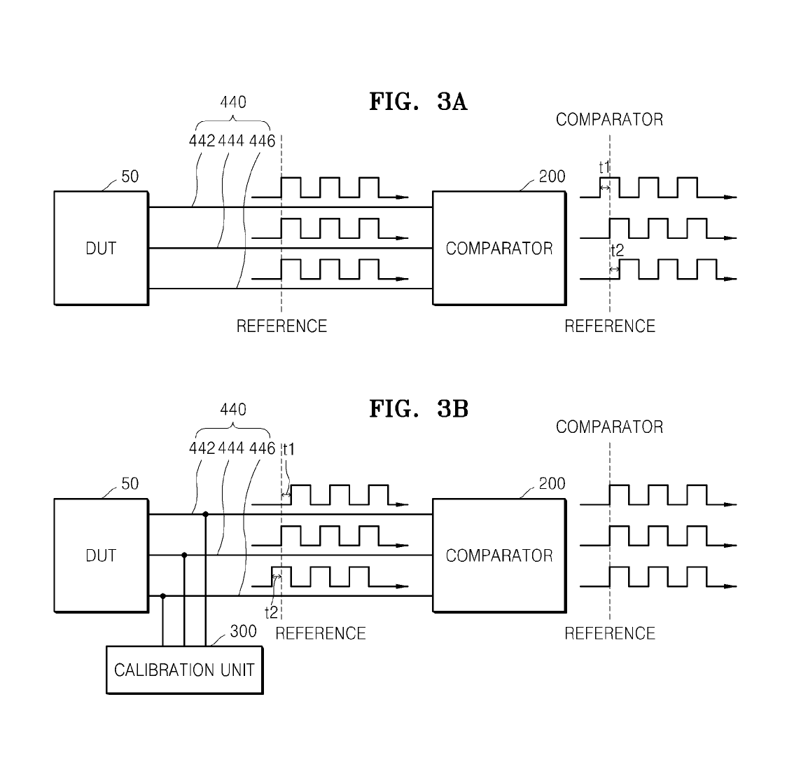

Calibration unit 300 may correct distortions of the input signal transmitted through input cable 420 and the output signal transmitted through output cable 440. More specifically, calibration unit 300 performs a function of correcting the distortions of the input signal and the output signal due to a test environment, such as a temperature variation of the test apparatus, resistances of input cable 420 and output cable 440, etc. in such a way that the DUT 50 precisely performs the test process. The function of calibration unit 300 will be described in more described with reference to FIGS. 2A through 3B.

Although calibration unit 300 of FIG. 1 is separated from controller 500, calibration unit 300 may be included in controller 500. That is, controller 500, such as a central processing unit (CPU) of the test apparatus, may perform the function of correcting distortions in the input signals and the output signal.

Server 400 may store the test program, and transmit the test program to signal generator 100 according to a request signal of calibration unit 300. The test program may include logic information used to generate the input signal applied to DUT 50. For example, if DUT 50 is a memory device, the test program may include logic information, such as a command, an address, and data, used to input data into memory cells of the memory device.

Controller 500 may perform a function of generally controlling the test apparatus. More specifically, controller 500 may generate a first operation signal for operating handler 600, a second operation signal for operating calibration unit 300, and a test request signal for operating signal generator 100. Furthermore, controller 500 may simultaneously transfer the first operation signal and the second operation signal to handler 600 and calibration unit 300 in such a way that handler 600 performs a step of loading the DUT 50. In addition, calibration unit 300 simultaneously performs a step of calibrating DUT 50.

When controller 500 simultaneously transfers the first operation signal and the second operation signal to handler 600 and calibration unit 300, DUT 50 may not be electrically connected to input cable 420 and the output cable 440. This is because DUT 50 is loaded by handler 600 and is not included in test chamber 630.

Therefore, during the step of calibrating DUT 50, performed according to the second operation signal, DUT 50 may not be electrically connected to input cable 420 and output cable 440 of the test apparatus. Further, since DUT 50 is loaded onto a test substrate 60 according to the first operation signal, during the step of calibrating DUT 50, some of the DUT 50 may not be connected to test substrate 60.

Handler 600 is used to handle DUT 50. In this regard, DUT 50 refers to processed objects of the test apparatus. For example, the DUT 50 may include volatile memory devices, such as SRAM, DRAM, SDRAM, etc., non-volatile memory devices, such as ROM, PROM, EPROM, EEPROM, flash memory, PRAM, MRAM, RRAM, FRAM, etc., and memory components including the above memories.

Furthermore, DUT 50 are not limited to memory devices or memory packages. For example, DUT 50 may include memory modules including a combination of memory components, memory cards, or memory sticks. Further, DUT 50 may include chips, such as image signal processors (ISP), digital signal processors (DSP) that include or do not include memory devices.

Handler 600 may include a loader 610, a soak chamber 620, the test chamber 630, an exit chamber 640, an unloader 650, and a handler controller 660 in order to handle DUT 50.

Loader 610 may load DUT 50. More specifically, loader 610 may load a DUT included in a tray, such as a customer tray (not shown), onto test substrate 60.

Soak chamber 620 may change the temperatures of DUT 50. More specifically, in order to test operation characteristics of DUT 50 at various temperatures, soak chamber 620 may heat or cool DUT 50 or the test substrate 50 including DUT 50, thereby changing the temperatures of DUT 50.

Test chamber 630 carries out an electrical test of DUT 50 that is changed to predetermined temperatures. To carry out the electrical test of DUT 50, test chamber 630 may be electrically connected to input cable 420 and output cable 440 of the test apparatus. Thus, input signals may be applied to DUT 50 included in test chamber 630 or output signals may be transmitted from DUT 50.

Exit chamber 640 is a place where DUT 50 for which the electrical test is carried out stand by before DUT 50 is unloaded. For example, when the electrical test is carried out for DUT 50 that are cooled, the exit chamber 640 may remove moisture from DUT 50 that stand by in exit chamber 640 and test substrate 60 including DUT 50.

Unloader 650 may unload DUT 50 onto customer trays (not shown) from test substrate 60. More specifically, unloader 650 may classify DUT 50 for which the electrical test is completely carried out into the non-defective and defective DUT 50, and unload the classified non-defective and defective DUT 50 onto respective trays.

Handler controller 660 may control operations of loader 610, test chamber 630, exit chamber 640, and unloader 650. For example, handler controller 660 may receive the first operation signal from controller 500 and operate loader 610, and thus loader 610 may perform the step of loading DUTs 50.

FIGS. 2A through 3B schematically illustrate synchronization levels of input signals and output signals transmitted when the input signals and the output signals are calibrated and are not calibrated, in order to explain a function of calibration unit 300, according to an exemplary embodiment.

Referring to FIG. 2A, input signals transmitted from signal generator 100 to DUT 50 may be distorted due to an external factor, such as a change in resistance of input cable 420 (according to variations of a length, a thickness, a temperature, etc.) and a change in a temperature of a test apparatus. For example, when synchronized input signals are transmitted to DUT 50 through first through third input cables 422, 424, and 426, timing skews of the input signals may occur in DUT 50 due to the distortion of the input signals. That is, the input signal is normally transmitted to the DUT 50 through second input cable 424, whereas the input signal may be transmitted to DUT 50 through first input cable 422, earlier than a reference time by t1, and the input signal may be transmitted to DUT 50 through third input cable 426 later than the reference time by t2. Such a timing skew factor may present an obstacle to precisely carrying out a test of DUT 50.

Meanwhile, referring to FIG. 2B, calibration unit 300 may prepare an calibration file of the first through third input cables 422, 424, and 426, and may partially correct timing of input signals based on the calibration file. For example, calibration unit 300 may transmit electrical signals to the first through third input cables 422, 424, and 426 before the test process is carried out, and measure a time taken to reflect and return the electrical signals. That is, calibration unit 300 may prepare the calibration file, including timing skew data of the first through third input cables 422, 424, and 426. Calibration unit 300 may use the calibration file to allow second input cable 424 to transmit the input signal generated by signal generator 100, first input cable 422 to transmit the input signal late by t1, and third input cable 426 to transmit the input signal early by t2. Therefore, timing skews of the input signals of the first through third input cables 422, 424, and 426 may be prevented, and the test process of DUT 50 may be precisely carried out.

Like FIG. 2A, referring to FIG. 3A, when DUT 50 transmits output signals to comparator 200 through first through third output cables 442, 444, and 446 without calibration unit 300, timing skews of the output signals may occur. That is, the output signal is normally transmitted to DUT 50 through the second output cable 444, whereas the output signal may be transmitted to DUT 50 through first output cable 442 earlier than a reference time by t1, and the input signal may be transmitted to DUT 50 through third output cable 446 later than the reference time by t2.

In this situation, referring to FIG. 3B, calibration unit 300 may prepare an calibration file including timing skew data of output cable 440 or load a previously prepared calibration file. Therefore, calibration unit 300 may use the calibration file to allow second output cable 444 to transmit the output signal from DUT 50 to comparator 200, first output cable 442 to transmit the output signal late by t1, and third output cable 446 to transmit the output signal early by t2. Therefore, timing skews of the output signals of the first through third output cables 442, 444, and 446 may be prevented, and the test process of DUT 50 may be precisely carried out.

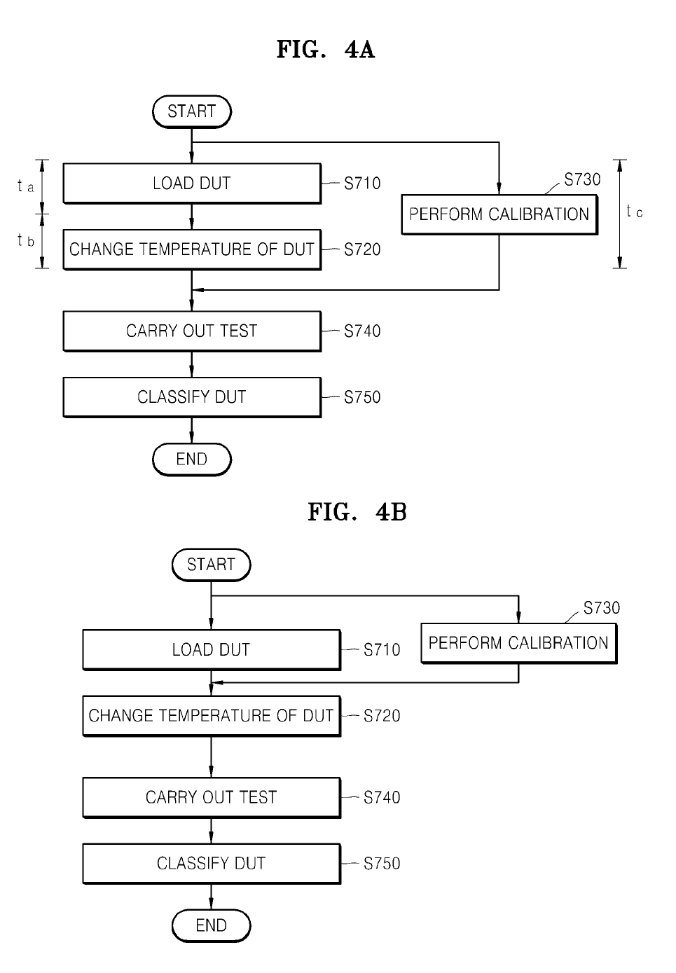

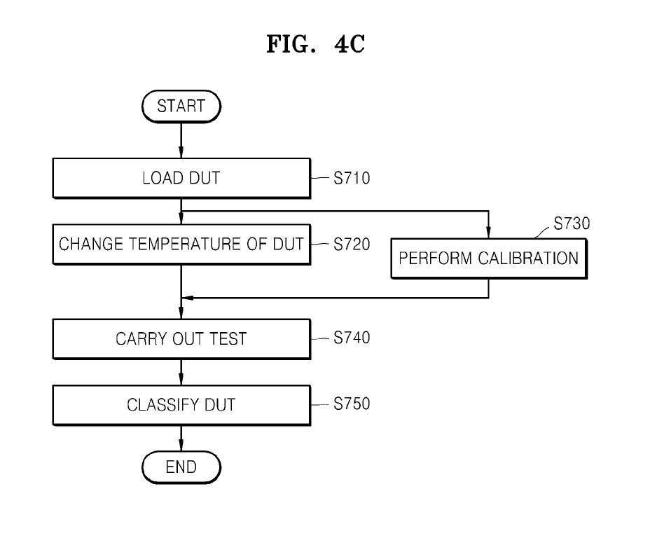

FIGS. 4A through 4C are schematic flowcharts of a test method of the DUT 50, according to exemplary embodiments. The test method of FIGS. 4A through 4C may be performed by using the test apparatus of FIG. 1. Thus, like elements denote like reference numerals, and redundant descriptions will not be repeated herein.

Referring to FIG. 4A, handler 600 performs a loading step (S710) of loading DUT 50 by using loader 610, and a soaking step (S720) of changing a temperature of DUT 50 by using soak chamber 620. Calibration unit 300 performs a calibration step (S730) of updating a test program received from server 400 or updating a calibration file.

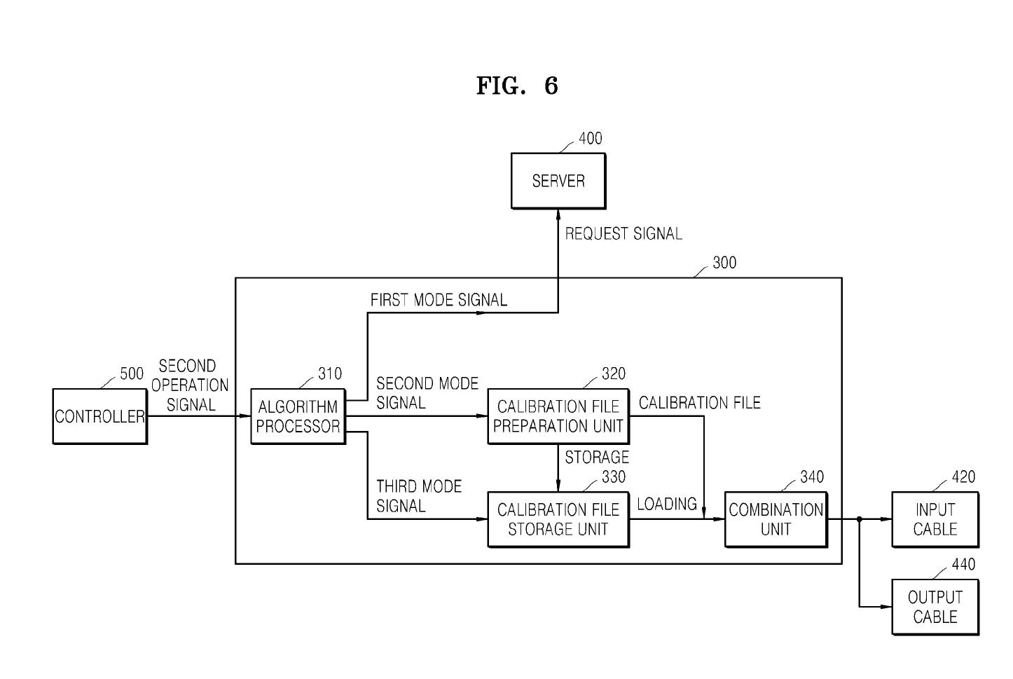

Updating may mean loading stored information or generating new information. For example, updating of the test program may mean loading a test program stored in server 400. Also, updating of the calibration file may mean loading a calibration file stored in a calibration file storage unit 330 (refer to FIG. 6) or preparing a new calibration file.

After calibration step (S730) is performed, a test step (S740) of carrying out an electrical test of DUT 50 may be performed based on the test program or the calibration file. During test step (S740), input signals input into DUT 50 and output signals output from DUT 50 may be calibrated by the calibration file. Thereafter, a classification step (S750) of classifying DUT 50 into the non-defective and defective DUT 50 may be performed.

Calibration step (S730) may be performed during loading step (S710) and soaking step (S720). In particular, calibration step (S730) may be performed simultaneously with loading step (S710). More specifically, controller 500 may simultaneously transfer the first operation signal and the second operation signal to handler 600 and calibration unit 300 as described with reference to FIG. 1, and thus, calibration step (S730) and loading step (S710) may be simultaneously performed.

Compared to the situation where calibration step (S730) is performed after loading step (S710) and soaking step (S720) are performed, when calibration step (S730) is performed during loading step (S710) and soaking step (S720), a test time loss may be prevented by a time taken to perform calibration step (S730). More specifically, during loading step (S710) and the soaking step (S720), controller 500, such as a CPU and calibration unit 300 are in an idle status. During such an idle time, calibration step (S730) of correcting distortions of the input signals and the output signals transmitted through input cable 420 and output cable 440 is performed, thereby preventing the test time loss by the time taken to perform calibration step (S730).

For example, if a time taken to perform loading step (S710) is ta, a time taken to perform soaking step (S720) is tb, and a time taken to perform calibration step (S730) is tc, a time may be reduced by ta+tb or tc in the exemplary embodiments. For example, if the time tc, taken to perform calibration step (S730), is longer than the time ta+tb taken to perform loading step (S710) and soaking step (S720), the time may be reduced by ta+tb. If the time tc taken to perform calibration step (S730) is shorter than the time ta+tb taken to perform loading step (S710) and soaking step (S720), the time may be reduced by tc.

Although calibration step (S730) is performed during the loading step (S710) and soaking step (S720) in FIG. 4A, the present inventive concept is not limited thereto. That is, calibration step (S730) may be performed in parallel with loading step (S710) or soaking step (S720), and thus the time taken to perform loading step (S710), the time taken to perform soaking step (S720), or the time taken to perform calibration step (S730), is reduced.

More specifically, referring to FIG. 4B, calibration step (S730) may be performed in parallel with loading step (S710). In this situation, calibration step (S730) may be performed simultaneously with loading step (S710). If the time taken to perform calibration step (S730) is longer than the time taken to perform loading step (S710), the time taken to perform loading step (S710) may be reduced. If the time taken to perform calibration step (S730) is shorter than the time taken to perform loading step (S710), the time taken to perform the calibration step (S730) may be reduced.

Referring to FIG. 4C, calibration step (S730) may be performed in parallel with soaking step (S720). In this situation, calibration step (S730) may be performed simultaneously with soaking step (S720). If the time taken to perform calibration step (S730) is longer than the time taken to perform soaking step (S720), the time taken to perform soaking step (S720) may be reduced. If the time taken to perform calibration step (S730) is shorter than the time taken to perform soaking step (S720), the time taken to perform calibration step (S730) may be reduced.

In a multi-kind and small-quantity product, like a multi-chip package (MCP), calibration step (S730) must be performed several times due to a change in a complex test process. In this situation, even though calibration step (S730) must be necessarily performed before an electrical test step is performed so as to match signals transmitted between the test apparatus and DUT 50, performing of calibration step (S730) several times causes an unnecessary loss of time in view of the test apparatus or a whole test process. However, the test apparatus and the test method of the present inventive concept perform calibration step (S730) in parallel with loading step (S710) and soaking step (S720), thereby preventing a time loss caused by performing calibration step (S730). That is, efficiency of the test apparatus or the test method may be improved.

During calibration step (S730), DUT 50 may not be electrically connected to input cable 420 and output cable 440. Calibration step (S730) and loading step (S710) are performed in parallel with each other, and thus DUT 50 is loaded onto substrate 50 by using handler 600 and is not included in test chamber 630 during calibration step (S730). Therefore, DUT 50 is not electrically connected to input cable 420 and output cable 440. Furthermore, since calibration step (S730) and loading step (S710) are simultaneously performed, some of DUT 50 may not be connected to test substrate 50 during calibration step (S730).

When calibration step (S730) is performed after loading step (S710) and soaking step (S720), DUT 50 may be included in test chamber 630. In this situation, during calibration step (S730), DUT 50 may be electrically connected to input cable 420 and output cable 440, which may result in a calibration error. However, the test apparatus and the test method of the present inventive concept do not electrically connect DUT 50 to input cable 420 and output cable 440 during calibration step (S730), and thus calibration step (S730) may be more precisely performed.

Further, when a conventional calibration error occurs, input cable 420 and output cable 440 must be disconnected from test substrate 60 to which DUT 50 is connected, and an additional calibration step must be performed. Meanwhile, the test apparatus and the test method of the present inventive concept do not electrically connect DUT 50 to test substrate 60, input cable 420, and output cable 440 during calibration step (S730), which corresponds to performing the additional calibration step.

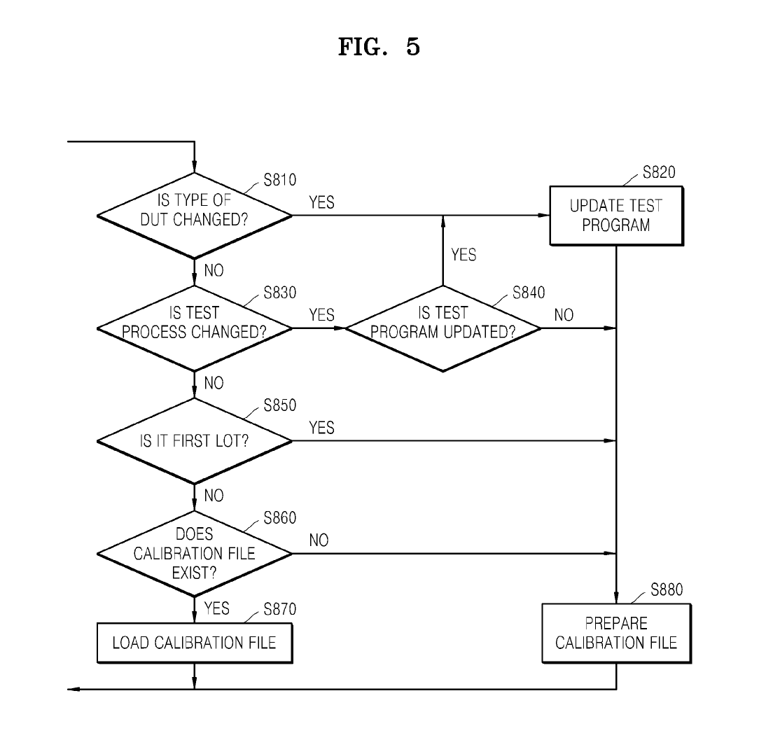

FIG. 5 is a schematic flowchart of calibration step (S730) of the test method of FIG. 4A, according to an exemplary embodiment. FIG. 6 is a schematic block diagram of calibration unit 300 included in test apparatus of FIG. 1. The redundant elements between FIGS. 5 and 6 and FIGS. 1 and 4A will not be described herein.

Referring to FIGS. 5 and 6, calibration unit 300 may include an algorithm processor 310, a calibration file preparation unit 320, a calibration file storage unit 330, and a combination unit 340.

Algorithm processor 310 processes algorithm used to perform calibration step (S73) according to a second operation signal. Specifically, algorithm processor 310 may transmit first through third mode signals in order to operate calibration file preparation unit 320 and/or calibration file storage unit 330, based on a variety of operation modes, such as a step (S810) of determining whether types of DUT 50 are changed, a step (S830) of determining whether a test process is changed, a step (S850) of determining whether DUT 50 is of a first lot, and a step (S860) of determining whether a calibration file exists.

As described above, calibration unit 300 may be included in controller 500. For example, algorithm processor 310 may be included in controller 500. In this situation, controller 500 may transmit and control signals to operate calibration file preparation unit 320 and/or calibration file storage unit 330, according to operational modes.

Algorithm processor 310 determines whether types of DUT 50 are changed (S810). If the types of DUT 50 are changed, since new input signals are applied according to changed DUT 50, the algorithm processor 310 performs a step (S820) of updating a test program. To this end, algorithm processor 310 may transmit a request signal that is the first mode signal to server 400. Server 400 in which the test program is stored may transmit the test program to signal generator 100 according to the request signal of calibration unit 300. Thus, the test program may be updated. Thereafter, to correct distortions of input signals and output signals, algorithm processor 310 transmits the second mode signal to calibration file preparation unit 320. Calibration file preparation unit 320 prepares a calibration file including timing skew data of input cable 420 and output cable 440.

When the types of DUT 50 are not changed, algorithm processor 310 determines whether a test process has changed (S830). Although the types of DUT 50 are the same as the previous ones, if the test process, such as a temperature condition, is changed, the test program should be changed. Thus, if the test process is changed, algorithm processor 310 determines whether the test program needs to be updated (S840). If the test program needs to be updated, algorithm processor 310 transmits a request signal that is the first mode signal to the server 400 to update the test program (S820). If the test program does not need to be updated, algorithm processor 310 transmits the second mode signal to calibration file preparation unit 320. Calibration file preparation unit 320 prepares calibration file (S880). The newly prepared calibration file may be stored in calibration file storage unit 330, and reused.

If the test program is not changed, algorithm processor 310 determines whether DUT 50 are of the first lot (S850). If DUT 50 is of the first lot, a calibration file must be prepared. If DUT 50 is of the first lot, algorithm processor 310 transmits the second mode signal to calibration file preparation unit 320. Calibration file preparation unit 320 prepares calibration file (S880). The newly prepared calibration file may be stored in calibration file storage unit 330, and reused as described above.

If DUT 50 are not of the first lot, algorithm processor 310 determines whether a calibration file exists (S860). If no calibration file exists, algorithm processor 310 transmits the second mode signal to calibration file preparation unit 320. Calibration file preparation unit 320 prepares calibration file (S880). The newly prepared calibration file may be stored in calibration file storage unit 330 and reused as described above. If the calibration file exists, algorithm processor 310 transmits the third mode signal to calibration file storage unit 330. Calibration file storage unit 330 loads the calibration file stored therein (S870).

If step (S740) of carrying out an electrical test of the DUT 50 is performed after calibration step (S730) is performed, combination unit 340 combines the calibration file and the input signals of input cable 420 and the output signal of output cable 440, and thus timing of the input signals and the output signals is corrected. Therefore, distortions of the input signals and the output signals may be corrected.

Although algorithm processor 310 is used to set the conditions for loading and preparing the calibration file in FIGS. 5 and 6, the present inventive concept is not limited to these conditions. For example, if a temperature of the test apparatus is changed to be higher than a predetermined temperature, the input signals and the output signals may be distorted due to the change in temperature of the test apparatus. Thus, algorithm processor 310 may detect the change in temperature of the test apparatus and prepare the calibration file. Also, algorithm processor 310 may prepare a new calibration file if the test apparatus stops operating due to an external factor, and operates again at a later time.

Further, although combination unit 340 is included in calibration unit 300 in FIG. 6, combination unit 340 may be included in the signal generator 100. In this situation, the calibration file prepared by calibration file preparation unit 320 and the calibration file loaded from calibration file storage unit 330 may be transmitted to signal generator 100. Signal generator 100 may generate an input signal calibrated based on the test program and the calibration files.

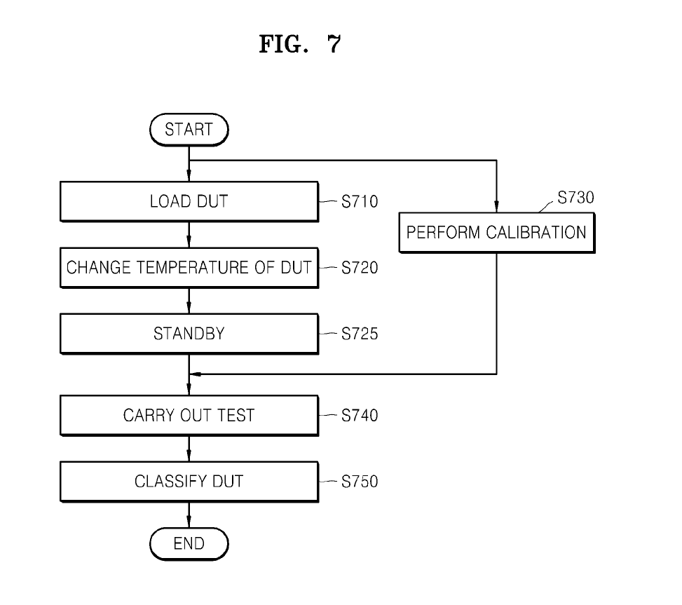

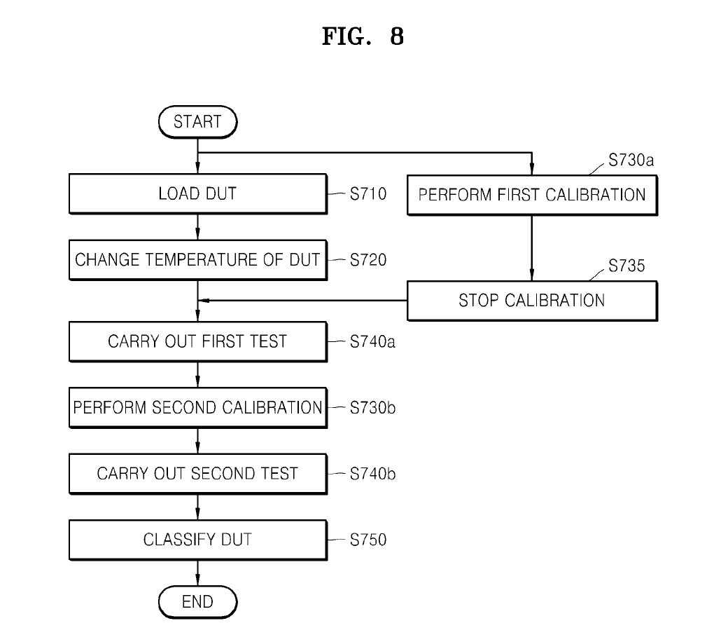

FIGS. 7 and 8 are schematic flowcharts of a test method of DUT 50, according to other exemplary embodiments. The test method of DUT 50 may be a modification of the test method of DUT 50 of FIG. 4A. The redundant descriptions between FIGS. 7 and 8 and FIG. 4A will not be repeated herein.

Referring to FIG. 7, if the time taken to perform calibration step (S730) is longer than the time taken to perform loading step (S710) and soaking step (S720), test step (S740) may be performed after calibration step (S730) is completed. In this situation, DUT 50 for which soaking is completed, stands by until calibration step (S730) is completed (S725).

Referring to FIG. 8, if the time taken to perform calibration steps (S730a and S730b) is longer than the time taken to perform loading step (S710) and soaking step (S720), test steps (S740a and S740b) may be performed during calibration steps (S730a and S730b). In this situation, calibration step (S730a) is stopped before test step (S740a). Calibration step (S730b) may be performed again after test step (S740a) is performed.

More specifically, if calibration steps (S730a and S730b) include a first calibration step (S730a) and a second calibration step (S730b), first calibration step (S730a) is performed during loading step (S710) and soaking step (S720), and a subsequent calibration step may be stopped (S735). Thereafter, a first test step (S740a) is performed based on a first calibration file prepared in first calibration step (S730a). Second calibration step (S730b) may be additionally performed after first test step (S740a) is performed. Thereafter, a second test step (S740b) is performed based on a second calibration file prepared in second calibration step (S730b).

As described above, during first calibration step (S730a), DUT 50 is not electrically connected to test substrate 60, input cable 420, and the output cable 440. Meanwhile, since the second calibration step (S730b) is performed after the first test step (S740a) is performed, during the second calibration step (S730b), the DUT 50 may be electrically connected to test substrate 60, input cable 420, and output cable 440.

While the inventive concept has been particularly shown and described with reference to exemplary embodiments thereof, it will be understood that various changes in form and details may be made therein without departing from the spirit and scope of the following claims.

What is claimed is:

1. A test method of at least one device under test (DUT), the test method comprising:
a loading step of loading the at least one DUT;
a soaking step of changing a temperature of the at least one DUT;
during at least one of the loading step and the soaking step, a calibration step of updating a test program stored in a server or updating a calibration file; and
a test step of carrying out an electrical test of the at least one DUT based on the test program or the calibration file.

2. The test method of claim 1, wherein the loading step and the calibration step are performed simultaneously.

3. The test method of claim 1, further comprising: a classification step of classifying the at least one DUT into defective and non-defective DUTs.

4. The test method of claim 1, wherein, during the calibration step, the at least one DUT is not connected to a test substrate.

5. The test method of claim 1, wherein during the calibration step, the at least one DUT is not electrically connected to an input cable and an output cable.

6. The test method of claim 1, wherein the test step is performed after the calibration step is completed.

7. The test method of claim 1, wherein the test step is performed during the calibration step, and the calibration step is stopped during the test step.

8. The test method of claim 7, wherein the stopped calibration step is performed again after the test step is performed.

9. The test method of claim 1, wherein the calibration step includes updating the test program according to whether types of the at least one DUT are changed or whether a test process is changed.

10. The test method of claim 1, wherein the calibration step includes updating the calibration file according to whether the calibration file is stored.

11. The test method of claim 10, wherein the updating of the calibration file includes in response to the calibration file being stored, loading the stored calibration file.

12. The test method of claim 10, wherein updating of the calibration file includes in response to the calibration file not being stored, preparing the calibration file.

13. The test method of claim 1, wherein the calibration step includes preparing the calibration file including timing skew data obtained by measuring a time taken to transmit electrical signals to the input cable or the output cable, reflect the electrical signals, and return the electrical signals.

14. The test method of claim 1, wherein, during the test step, input signals input into the at least one DUT and output signals output from the at least one DUT are calibrated according to the calibration file.

15. A test method of at least one DUT, the test method comprising:
a loading step of loading the at least one DUT;
a soaking step of changing a temperature of the at least one DUT;
a first calibration step of updating a first calibration file during at least one of the loading step and the soaking step; and
a first test step of carrying out an electrical test of the at least one DUT based on the first calibration file.

16. A test apparatus for testing at least one device under test (DUT), the test apparatus comprising:
a loader which loads the at least one DUT;
a soak chamber which changes a temperature of the at least on DUT,
a calibration unit which updates a test program stored in a server or updating a calibration file, and
a test unit which carries out an electrical test of the at least one DUT based on the test program or the calibration file.

17. A test apparatus for at least one DUT, the test apparatus comprising:
a controller;
a handler which receives a first operation signal from the controller;
a loader which loads the at least one DUT;
a soak chamber which varies a temperature of the at least one DUT;
a signal generator which generates an input signal applied to the at least one DUT based on a test program;
a comparator which receives an output signal of the at least one DUT and determines whether the at least one DUT is defective;
a calibration unit which receives a second operation from the controller, and corrects distortions of the input signal and the output signal, wherein the controller simultaneously transfers the first operation signal and the second operation signal to the handler and the calibration unit.

18. The test apparatus of claim 17 further comprising:
an input cable which transmits the input signal, and an output cable for transmitting the output signal, wherein, when the controller simultaneously transfers the first operation signal and the second operation signal to the handler and the calibration unit, the input cable and the output cable are not electrically connected to the at least one DUT.
